(19) United States
(12) Patent Application Publication
(10) Pub. No.: US 2007/0132520 A1
(43) Pub. Date: Jun. 14, 2007

(54) Method for voltage controlled oscillator yield enhancement

(75) Inventor: Abdellatif Bellaouar, Richardson, TX (US)

Correspondence Address: BORDEN LADNER GERVAIS LLP, 1100-100 QUEEN ST, OTTAWA, ON, K1P 1J9, CA

(73) Assignee: SiRiFIC WIRELESS CORPORATION

(21) Appl. No.: 11/296,536

(22) Filed: Dec. 8, 2005

(51) Int. Cl. H03B 5/08

(52) U.S. Cl. 331/167

(57) ABSTRACT

A method of selecting fabrication parameters for an on-chip inductor of an integrated circuit. The integrated circuit includes a capacitor fabricated prior to the inductor. The capacitance of the capacitor is measured and, based on the measured capacitance and on a desired frequency range, a suitable inductor is fabricated. The integrated circuit may include a voltage controlled oscillator (VCO), and the selection of the fabrication parameters of the inductor includes the selection of a lithography mask for the fabrication of the inductor for maximizing yield across the wafer. Therefore, the integrated circuit can have exactly one VCO for covering the desired frequency range, as opposed to at least two VCO's with overlapping frequency ranges, thereby saving significant silicon area and increasing the yield per wafer.

### FIELD OF THE INVENTION

The present invention relates generally to a manufacturing method for integrated circuits comprising inductors. More particularly, the present invention relates to a manufacturing method for enhancing the yield of integrated circuits having voltage controlled oscillators comprising inductors.

### BACKGROUND OF THE INVENTION

Inductors are widely used in signal processing systems and circuits such as television systems, radar systems, communication systems, band-pass filters and tank circuits. Progress in signal processing systems and circuits has come with integration and miniaturization of circuits to the point where such systems and circuits can now easily be integrated on a chip. However, due to the intrinsic nature of inductors, it has not been possible to scale their dimensions at the same rate as other circuit components such as transistors, capacitors, diodes etc. Some work has been done in substituting inductors with inductor simulating circuits with results often being unworkable due to high parasitic effects of the simulated inductor circuits.

In integrated systems and circuits where simulated inductor circuits cannot be used, spiral-type inductors are fabricated on the same chip as the rest of the integrated circuit with the consequence of the inductor occupying a disproportionately large surface area compared to the rest of the circuit components. This problem is exacerbated in circuits where multiple inductors are sometimes necessary, such as in integrated circuits having multiple voltage controlled oscillator circuits.

Voltage controlled oscillators (VCOs) are well-known and widely used in the electronics industry. In the field of radio frequency (RF) communications, VCOs generate an oscillating output signal having a specified frequency and can be used, for example, in clock recovery or frequency synthesizing applications.

VCOs are commonly part of monolithic semiconductor integrated circuits (ICs) and application specific integrated circuits (ASICs). Numerous modern digital integrated circuits are fabricated using well known and widely used CMOS technology. Where the VCO is included in a CMOS IC, the VCO is usually fabricated in CMOS. For cost, material yield and electrical noise reasons, it is often advantageous to have chip components, including any VCOs, occupy as little area as possible; however. this is not always easy to accomplish as illustrated below.

A circuit representation of a VCO 20 is shown in FIG. 1 where a negative resistance (-R) load 22 is connected to a tuning capacitor 24, often a varactor, a capacitor 32, and an inductor 26 to produce an output signal OUT together with its complementary output signal O̅U̅T̅. Those of skill in the art will understand that capacitor 32 represents a capacitance that can be provided by more than one capacitor.

Fabrication processes of VCOs, such as VCO 20, are well known in the art. The first step in the fabrication of an IC including a VCO is that of the formation of the transistor structures on a semiconductor substrate. This is usually carried out through a series of processing steps for defining transistor structures such as poly-silicon gates and active area together with metal interconnects. A photolithographic process defines transistors and metallization regions. The photolithography process will usually include deposition of a photoresist on the substrate, covering of the photoresist with a mask having a predetermined pattern defining parts of the transistors, applying light to the photoresist through the mask, removing the exposed photoresist and etching or otherwise treating the sections of the substrate uncovered by the removal of the exposed photoresist.

The substrate sections having been subjected to a photolithography process such a described above can be n-doped or p-doped by ion-implantation technology as is known in the art. These ion-implanted regions provide the building blocks for the formation of the transistors. Subsequent steps of photolithography and of deposition of poly-silicon for the formation of transistor gates completes the formation of the transistor layer. A typical mask also includes not only patterns for the fabrication of transistors but also patterns for the fabrication of other components, such as capacitors.

Once the transistor layer is completed, subsequent layers of metal and dielectric, or insulating material, are deposited in order to interconnect the transistors. Additionally, other components such as inductor 26 can be included in these subsequent layers. It is not uncommon to have at least 5 metallization layers in a given integrated circuit.

The fabrication of inductors such as inductor 26 is known in the art. Inductor 26 is usually a spiral inductor which, as noted above, can consume a large surface area relative to the area of the rest of the circuit.

VCOs of interest include those based on silicon, as well as those based on other semiconductors or semiconductor compounds, such as GaAs and SiGe, and/or organic semiconductors. VCOs of interest also include those fabricated in CMOS, bipolar and other technologies.

VCO 20 is designed to produce, upon application of a voltage V_{c} to the varactor 24 and by digitally changing the capacitance of capacitor 32 via a digital adjustment signal V_{adj} controlling one or more of the capacitors represented by.capacitor 32. For example, oscillations of the output signals at a frequency in a range can be delimited by minimum and maximum frequencies fₘᵢₙ and fₘₐₓ For a given inductance value of inductor 26, the oscillation frequency is predominantly determined by digitally adjusting capacitor 32, which has a max value and a minimum value at which oscillations occur. The max value produces the minimum frequency value and the min value produces the maximum frequency value. The inductance value of inductor 26 is determined in conjunction with the frequency requirements of VCO 20, and the nominal values of the other components of the oscillatory circuit that is VCO 20.

Capacitor 32, which can be a plurality of capacitors having a max and min capacitance value as mentioned above, can include a metal-dielectric-metal structure and can be formed in parallel with tuning capacitor 24 to allow operation of VCO 20 at the nominal voltage value V_{c.} Unfortunately, variations in manufacturing processes and/or variations in manufacturing plants, allow for large variances in the value of the minimum and maximum values of capacitor 32, the accuracy of which sometimes being no better than 20%.

The deleterious effect of the large variance in minimum and maximum values of the capacitance of capacitor 32 is illustrated in FIG. 2a where a graph depicts the desired tuning range 36 (having endpoints fₘᵢₙ and fₘₐₓ) together with the nominal tuning range 38 of VCO 20. The endpoints of nominal tuning range 38 are usually set beyond those of the desired tuning range 36 to accommodate manufacturing variations in VCO 20. As depicted by tuning range 38, if the nominal minimum and maximum capacitance values of capacitor 32 is attained in the fabrication process, operation of VCO 20 at frequencies between fₘᵢₙ and fₘₐₓ is feasible.

Range 42 depicts a case where the minimum and maximum capacitance values of capacitor 32 are markedly different from their nominal values. In this case, defective tuning range 42 of tuning capacitor 24 does not permit VCO 20 to function at values near the fₘᵢₙ end of the range due to a shift towards high frequencies of defective tuning range 42 with respect to range 38. Chips with tuning ranges such as defective range 42 are rejected, which consequently leads to low manufacturing yields and higher manufacturing costs.

For this reason, designers will often include multiple VCOs in their circuit design in order to accommodate for manufacturing variations in the minimum and maximum capacitance values of tuning capacitor 32. FIG. 2b illustrates the case where two VCOs, having tuning ranges 44 and 46 respectively, are formed to cover jointly the desired frequency range fₘᵢₙ to fₘₐₓ. Ranges 44 and 46 have sufficient width and overlap, such that, when frequencies near fₘᵢₙ are required, the VCO having range 44 is selected, and when frequencies near fₘₐₓ are required, the VCO having range 46 is selected. Intermediate frequencies can be achieved in either range 44 or 46. Means for selecting the operation of specific VCOs are known in the art. The VCOs with ranges 44 and 46 differ in their inductance value of inductor 26.

The main disadvantage of providing more than one VCO on a chip lies in the surface area consumed by each VCO, particularly by inductor 26 which, in VCOs for RF applications, can typically occupy an area as high as 400 μm×400 μm, which is several times the surface area occupied by the VCO components other than the inductor. In instances where two, three or more VCOs are needed to accommodate a desired frequency range, the total surface area occupied by the inductors become prohibitively very large and costly. The on-chip inductors dominate the total circuit area and can dominate the total chip area, relative to the other circuit components.

FIG. 3 depicts an IC 50 with two VCO circuit blocks 52 comprising inductors 26. The large area occupied by inductor 26 relative to the area occupied by the VCO components other than the inductor, symbolized by circuit blocks 27, is apparent. It is noted that FIG. 3 is not to scale, and is only used to illustrate the relative difference in areas.

Therefore, it is desirable to provide a manufacturing method that allows ICs having sub-circuits comprising inductors (such sub-circuits being, for example, VCOs or inductors themselves) to have high manufacturing yield while minimizing, sometimes to one, the number of sub-circuits in the IC.

### SUMMARY OF THE INVENTION

It is an object of the present invention to obviate or mitigate at least one disadvantage of previous VCO circuit fabrication methods. In particular, the object of the present invention is to provide a method for improving manufacturing yield for circuits having only a single VCO circuit with an on-chip inductor for covering a wide operating frequency range.

In a first aspect, the present invention provides a method of fabricating a voltage controlled oscillator (VCO) having a predetermined frequency range set by a capacitor and inductor circuit. The method includes fabricating components of the VCO except an on-chip inductor, fabricating a test capacitor, measuring the capacitance of the test capacitor, and fabricating the on-chip inductor. The fabricated components can include the capacitor for electrical connection to the on-chip inductor. The capacitor can include an array of parallel connected capacitors digitally controllable for adjusting a capacitance value thereof. The test capacitor is fabricated as the components of the VCO are fabricated. The on-chip inductor has a predetermined value, where the predetermined value is selected to obtain the predetermined frequency range based on the measured capacitance of the test capacitor.

According to embodiments of the present aspect, the test capacitor is fabricated as part of a process control module, or the test capacitor is fabricated in a scribe area. The step of fabricating can include calculating the capacitance of the capacitor corresponding to the measured capacitance of the test capacitor, and can further include determining the predetermined value of the on-chip inductor to obtain the predetermined frequency with the calculated capacitance of the capacitor. Altemately, the step of fabricating can include selecting the predetermined value from a look-up table having measured capacitances and corresponding predetermined values, where the predetermined value can be a closest corresponding predetermined value in the look-up table. Subsequently, an inductor lithography mask corresponding to the selected predetermined value can be selected. According to another embodiment, the components of the VCO can be fabricated in a first fabrication chamber and the on-chip inductor can be fabricated in a second fabrication chamber.

In a second aspect, the present invention provides a method of fabricating a plurality of dies on a wafer, each die having a voltage controlled oscillator (VCO) circuit having a predetermined frequency range set by a capacitor and inductor circuit. The method includes fabricating components of each VCO, fabricating a test capacitor, measuring a capacitance of the test capacitor, determining a value of the on-chip inductor, and fabricating the on-chip inductors. The components of each VCO are fabricated except for an on-chip inductor, where the components of each VCO can include the capacitor for electrical connection to the on-chip inductor. The test capacitor can be fabricated as the components of the VCO are fabricated. The value of the on-chip inductor can be determined for obtaining the predetermined frequency range based on the measured capacitance of the test capacitor. The fabricated on-chip inductors can each have the same determined value.

According to embodiments of the present aspect, the step of determining can include determining the value of the on-chip inductor for maximizing yield of the wafer. The test capacitor can be fabricated as part of a process control module. The step of determining can include calculating the capacitance of the capacitor corresponding to the measured capacitance of the test capacitor, and then determining the predetermined value of the on-chip inductor to obtain the predetermined frequency with the calculated capacitance of the capacitor.

In further embodiments, the step of determining can include selecting the predetermined value from a look-up table having measured capacitances and corresponding predetermined values, and then selecting an inductor lithography mask corresponding to the selected predetermined value. The predetermined value can be a closest corresponding predetermined value in the look-up table. The components of each VCO can be fabricated in a first fabrication chamber and the on-chip inductors can be fabricated in a second fabrication chamber.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts a simplified voltage controlled oscillator;

FIGS. 2a and 2b depict examples of frequency range coverage for a VCO;

FIG. 3 is a plan view of a layout of an integrated circuit including two VCO circuits;

FIG. 4 depicts an integrated circuit having a VCO region including a process control monitor;

FIG. 5 is a graph of required inductance of the inductor of FIG. 1 as a function or measured capacitance of the capacitor of FIG. 1; and

FIG. 6 is a flow chart illustrating an embodiment of the method of the present invention.

### DETAILED DESCRIPTION

A method of selecting fabrication parameters for an on-chip inductor of an integrated circuit is described. The integrated circuit includes a capacitor fabricated prior to the inductor. The capacitance of the capacitor is measured and, based on the measured capacitance and on a desired frequency range, a suitable inductor is fabricated. The integrated circuit may include a voltage controlled oscillator (VCO), and the selection of the fabrication parameters of the inductor includes the selection of a lithography mask for the fabrication of the inductor for maximizing yield across the wafer. Therefore, the integrated circuit can have exactly a single VCO for covering the desired frequency range, as opposed to at least two VCO's with overlapping frequency ranges, thereby saving significant silicon area and increasing the potential yield per wafer.

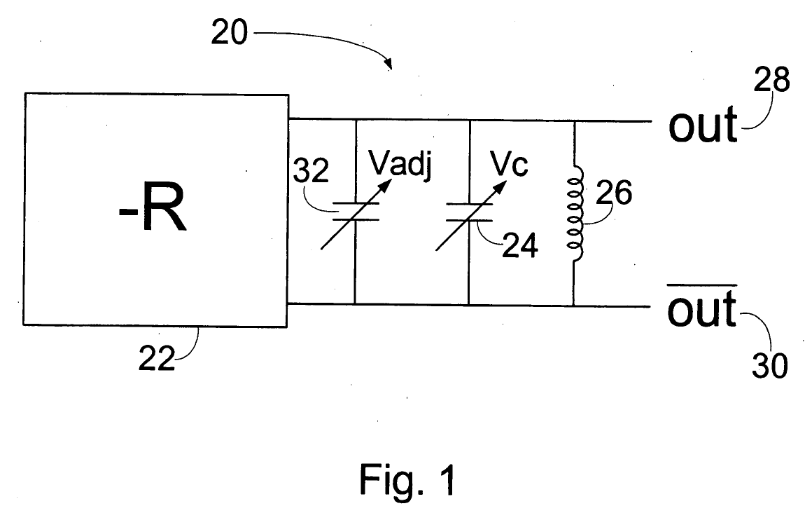

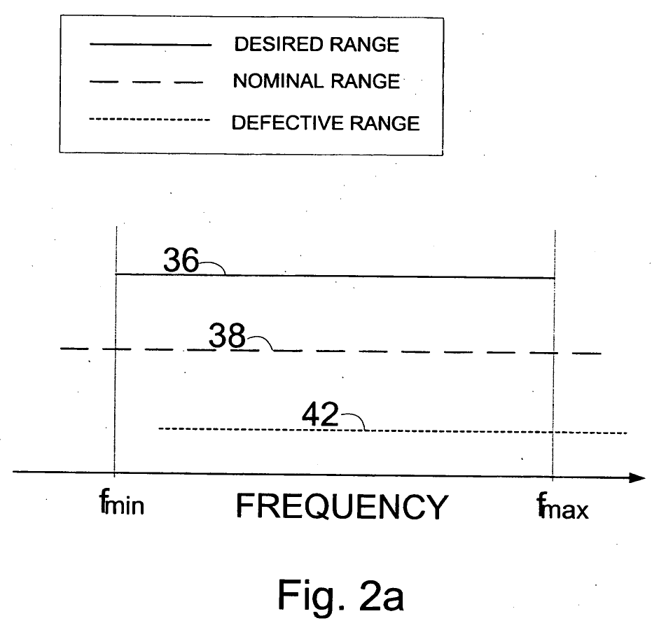

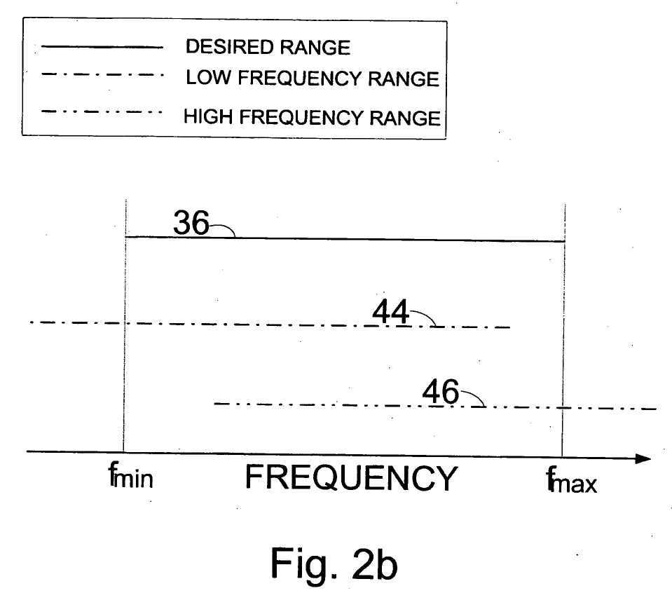

The examples described below relate particularly to ICs comprising VCOs with inductors and to minimizing the number of VCOs required to satisfy operating frequency range requirements of the ICs. The ICs can be of any type including those fabricated using CMOS, bipolar or other technologies. The present invention encompasses all types of VCOs, including VCO 20 shown in FIG. 1 and VCOs having their frequency set by a current rather than a voltage, as long as they have an inductor. Yield enhancement of ICs having VCOs is achieved as described below.

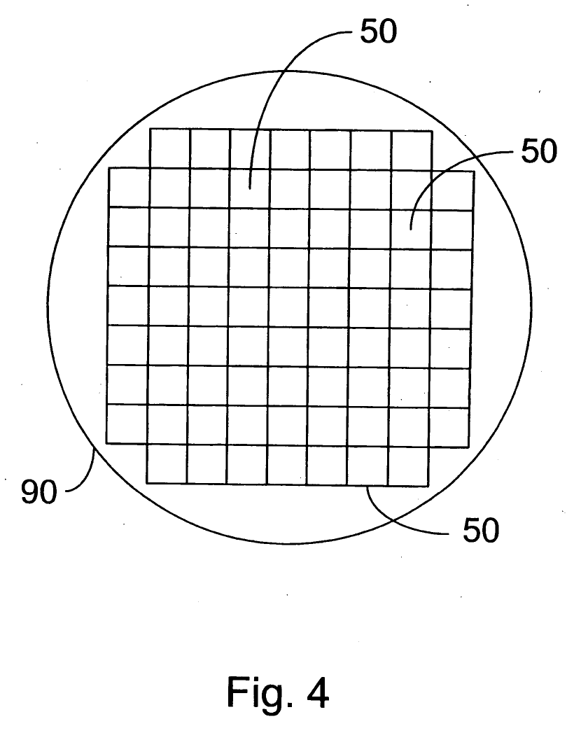

The fabrication steps of the ICs and of VCO 20 are carried out up to the fabrication step of inductor 26. That is, the transistors are fabricated, as are the capacitors, including capacitor 32 with its potentially varying min and max values and capacitor 24, and other electronic components. This is followed by the interconnection of the transistors and the other components through several layers of metallization and deposition of dielectric layers. As will be understood by a worker skilled in the art, these steps are performed in a wafer fabrication and processing environment where, as shown in FIG. 4, a plurality of ICs 50 are fabricated on a wafer 90.

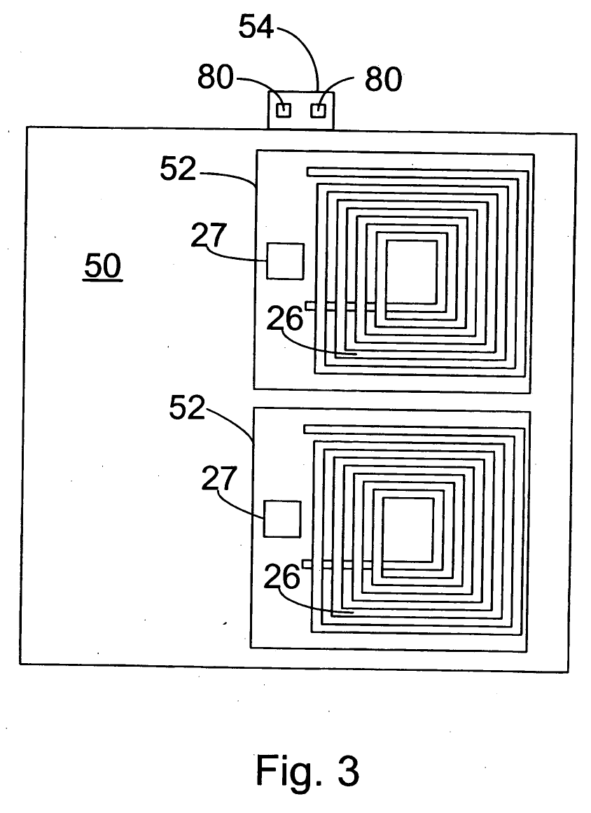

Additionally, as shown in FIG. 3, at least one test structure, well known in the art as a process control monitor (PCM) 54 is fabricated on wafer 90, adjacent IC 50. One or more process control monitors are formed in the scribed areas between chips on the wafer, and are used to monitor manufacturing process parameters. Process control monitors are added by the manufacturing facility, and can include structures such as transistors and capacitors. Therefore, a corresponding capacitance value of capacitor 32 or equivalent array of capacitors, can be obtained through probing the PCM. The PCM 54 includes a capacitor and test pads 80 accessible with probes connected to a measurement apparatus such as, for example, a capacitance meter. Each pad 80 is electrically connected to one of the metallization layers making up the capacitor of PCM 54.

Capacitor 32 with its min and max capacitance values, which can include a plurality of capacitors (as mentioned above), and the capacitor formed in the PCM 54 can be formed in the same fabrication steps to include substantially the same dielectric and metallization layers. As such, they can differ, a priori, only in their surface area. Consequently, a look-up table relating the capacitance of capacitor 32 to that of PCM 54 can be created by either, a priori measurements of test capacitor circuits fabricated on a separate wafer can be done at approximately the same time and in the same fabrication chamber as the ICs of wafer 90, or by calculation. If the surface area of the capacitors are the same, then it is not necessary to create a lookup table since the capacitance of capacitor 32 and that of process data region 54 should be the same. Either way, measuring the capacitance of PCM data region 54 can provide a capacitance value of capacitor 32 or for an equivalent capacitor array. If desired, a test capacitor can be formed on the IC itself for direct measurement, thereby alleviating the need for PCM 54.

In FIG. 3, PCM 54 is shown as being outside IC 50. PCMs 54 and test pads 80 can be formed in the scribe area between the ICs 50 shown in FIG. 4. However, PCM 54 and test pads 80 can also be formed anywhere on IC 50.

As will be understood by a skilled worker in the art, the capacitance of capacitor 32 and tuning capacitor 24 together with the inductance of inductor 26 are the primary quantities affecting the frequency range of VCO 20. Furthermore, as in a basic LC circuit, an increase of the capacitance of capacitor 32 (or parallel array of capacitors), leading to a decrease in the frequency range of VCO 20, can be compensated by a decrease in the inductance of inductor 26, and vice versa. Thus, by knowing the required nominal frequency range and, by measuring the capacitance, it is possible to calculate the inductance required to attain the nominal frequency range and to fabricate inductor 26 accordingly.

Methods of fabricating inductor 26 are known in the art. The inductor 26 can be a spiral-type inductor (as depicted in FIG. 3) whose fabrication includes a photolithography process where a mask having a spiral geometry defines the inductor geometrical pattern subsequently filled with metal during a metallization step. The parameters of the inductor are essentially geometrical in nature and include, for example, the width of the metal tracks, the number of spires, the radius each spire together with the metal type and the metal quality. Fabrication of inductor 26 typically occurs in the last metallization step but can also take place earlier with additional overlying interconnect layers being formed if required.

Many lCs 50 are fabricated together on a wafer 90 as shown in FIG. 4. As is known in the art, while it is possible that the capacitor 32, which can include a plurality of capacitors, present on each IC 50 will be markedly different from each other, in all likelihood there will be only a small variance between them. Consequently, most of ICs 50 from wafer 90 will be operational within specifications with the same inductance value inductor 26.

Thus, before fabricating inductor 26, a test capacitance related to the capacitance of capacitor 32 on wafer 90 is measured through a measurement of the capacitance of PCM 54. The required inductance value of inductor 26 is then determined based on the measured test capacitance, which is related to capacitor 32 having a max and min value. It will be understood that measuring the capacitance of more than one PCM 54 on the wafer is not absolutely required since the PCMs will usually have substantially the same capacitance.

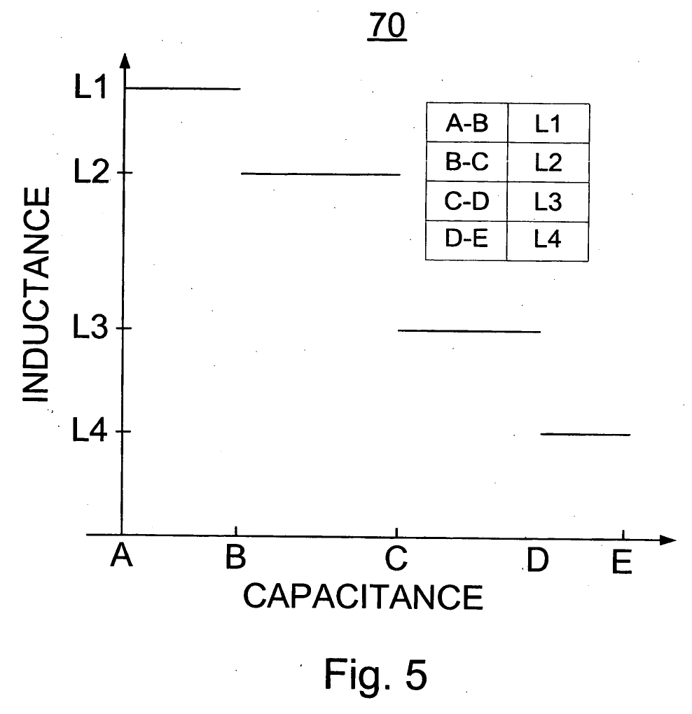

Once the required inductance of inductor 26 has been determined, an inductor lithography mask for wafer 90 can be specifically formed or selected from a series of pre-fabricated masks, each mask designed to provide a specific inductance value inductor on each IC. The selected mask can be the one providing the highest yield of ICs. The selection of the mask can be achieved through a cross-reference table listing capacitance value ranges and corresponding inductances. This is illustrated in the example of FIG. 5 where graph 70 depicts a series of four inductances L1, L2, L3 and L4 partitioning the range of capacitance determined through PCM 54. In the example of FIG. 5, if the measured capacitances have a value between A and B, the inductor mask yielding an inductance L1 is selected. If the measured capacitances are between values B and C, then the inductor mask yielding an inductance L2 is selected and so forth for other capacitance values. The example of FIG. 5 depicts one to four masks. In practice, any number of masks is possible. The selected mask is then used to fabricate inductors 26 on wafer 90 followed by subsequent fabrication steps if need be.

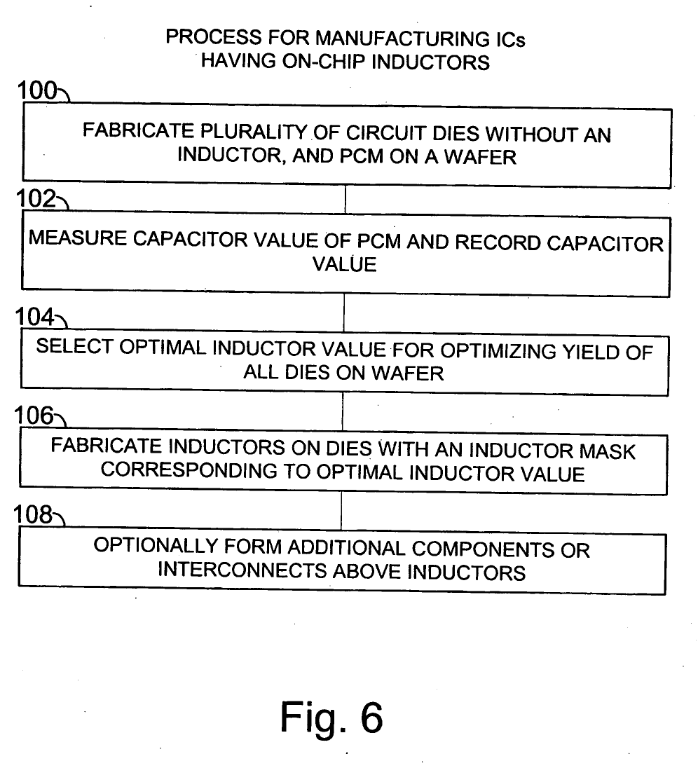

FIG. 6 shows a flow chart illustrating an example of a process of manufacturing ICs having on-chip inductors. At step 100, a plurality of IC dies are fabricated on a semiconductor wafer (substrate), where each IC die can have transistors, resistors and capacitor components for example. This step will include the complete fabrication of the circuits, without the inductor being formed. As previously discussed, at least one PCM will be formed on the wafer scribe areas, where the PCM will have a testable capacitor structure. At step 102, the capacitor value of the PCM is measured and recorded. An optimal inductor value for optimizing the yield of ICs is determined at step 104. At step 106, an inductor mask for providing the inductance value of step 108 is selected and the inductors are fabricated on the IC dies. Finally, at step 108, the additional metallization, such as bussing, can be fabricated if need be.

As is known in the art, processes for fabricating and testing integrated circuits can be automated. In the present embodiment of the invention, selecting a mask for forming inductor 26 can be based on data collected from the PCM 54 and can be easily automated as will be understood by a worker having ordinary skill in the art.

Inductors 26 sometimes require particular steps in their fabrication in order to ensure optimum performance of VCO 20. In some cases, a fabrication chamber well suited for the fabrication of components other than inductor 26 is inadequate or only marginally adequate for the fabrication of inductor 26 (for example, an inductor 26 may require a thick metal not available in the fabrication chamber used in the fabrication of the components other than inductors). In order to overcome this problem, it is possible to fabricate inductor 26 in a fabrication chamber well suited for, and perhaps dedicated to, this task. That is, a partially completed integrated circuit 50, without inductor 26, can be removed from the fabrication chamber and brought to another fabrication chamber where a particular metal, or a particular metal quality, is available for fabricating inductor 26. This is particularly well suited to a fabrication process where inductor 26 is the last layer to be formed on integrated circuit 50. If need be, fabrication steps subsequent to the fabrication of inductor 26 can be performed in the fabrication chamber used for inductor 26 or in another chamber, including the initial chamber.

Thus, by determining the minimum and maximum capacitance values of capacitor 32 through a measurement of a test capacitance via PCM 54, and by using those capacitance values for selecting a lithography mask for inductor 26, the present invention provides a method for enhancing the production yield of integrated circuits having VCOs without having to include multiple VCOs to satisfy frequency range requirements. ICs having only one VCO instead of multiple VCOs are feasible.

The present invention was presented in the context of integrated circuits where VCOs are used, inductor 26 was a part of a VCO. It will be clear to one having ordinary skill in the art that the present invention applies to any integrated circuit where an inductor is fabricated subsequent to a capacitor, the inductor and the capacitor being electrically connected.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A method of fabricating a voltage controlled oscillator (VCO) having a predetermined frequency range set by a capacitor and inductor circuit, the method comprising:
a) fabricating components of the VCO except an on-chip inductor, the components including the capacitor for electrical connection to the on-chip inductor;
b) fabricating a test capacitor;
c) measuring the capacitance of the test capacitor; and,
d) fabricating the on-chip inductor having a predetermined value, the predetermined value being selected to obtain the predetermined frequency range based on the measured capacitance of the test capacitor.

2. The method of claim 1, wherein the test capacitor is fabricated as part of a process control module.

3. The method of claim 1, wherein the test capacitor is fabricated in a scribe area.

4. The method of claim 1, wherein the step of fabricating includes calculating the capacitance of the capacitor corresponding to the measured capacitance of the test capacitor.

5. The method of claim 4, further including determining the predetermined value of the on-chip inductor to obtain the predetermined frequency with the calculated capacitance of the capacitor.

6. The method of claim 1, wherein the step of fabricating includes selecting the predetermined value from a look-up table having measured capacitances and corresponding predetermined values.

7. The method of claim 5, further including selecting an inductor lithography mask corresponding to the selected predetermined value.

8. The method of claim 1, wherein the step of fabricating includes selecting the predetermined value from a look-up table having measured capacitances and corresponding predetermined values, the predetermined value being a closest corresponding predetermined value in the look-up table.

9. The method of claim 5, further including selecting an inductor lithography mask corresponding to the selected predetermined value.

10. The method of claim 1, wherein the components of the VCO are fabricated in a first fabrication chamber and the on-chip inductor is fabricated in a second fabrication chamber.

11. The method of claim 1, wherein the capacitor can include an array of parallel connected capacitors digitally controllable for adjusting a capacitance value.

12. A method of fabricating a plurality of dies on a wafer, each die having a voltage controlled oscillator (VCO) circuit having a predetermined frequency range set by a capacitor and inductor circuit, the method comprising:
a) fabricating components of each VCO except an on-chip inductor, the components of each VCO including the capacitor for electrical connection to the on-chip inductor;
b) fabricating a test capacitor as the components of the VCO are fabricated;
c) measuring a capacitance of the test capacitor;
d) determining a value of the on-chip inductor for obtaining the predetermined frequency range based on the measured capacitance of the test capacitor; and, e) fabricating the on-chip inductors, each on-chip inductor having the determined value.

13. A method of claim 12, wherein the step of determining includes determining the value of the on-chip inductor for maximizing yield of the wafer.

14. The method of claim 12, wherein the test capacitor is fabricated as part of a process control module.

15. The method of claim 12, wherein the step of determining. includes calculating the capacitance of the capacitor corresponding to the measured capacitance of the test capacitor.

16. The method of claim 15, further including determining the predetermined value of the on-chip inductor to obtain the predetermined frequency with the calculated capacitance of the capacitor.

17. The method of claim 12, wherein the step of determining includes selecting the predetermined value from a look-up table having measured capacitances and corresponding predetermined values.

18. The method of claim 17, further including selecting an inductor lithography mask corresponding to the selected predetermined value.

19. The method of claim 12, wherein the step of determining includes selecting the predetermined value from a look-up table having measured capacitances and corresponding predetermined values, the predetermined value being a closest corresponding predetermined value in the look-up table.

20. The method of claim 19, further including selecting an inductor lithography mask corresponding to the selected predetermined value.

21. The method of claim 12, wherein the components of each VCO are fabricated in a first fabrication chamber and the on-chip inductors are fabricated in a second fabrication chamber.
